(19) United States
(12) Patent Application Publication
(10) Pub. No.: US 2006/0105558 A1
(43) Pub. Date: May 18, 2006

(54) Inter-metal dielectric scheme for semiconductors

(76) Inventors: Harry Chuang, Hsin-Chu (TW); Chen-Hua Yu, Hsin-Chu (TW); Po-Hsiung Leu, Taoyuan County (TW); Szu-An Wu, Hsin-Chu (TW)

Correspondence Address: SLATER & MATSIL, L.L.P., 17950 PRESTON ROAD, SUITE 1000, DALLAS, TX, 75252, US

(21) Appl. No.: 10/992,161

(22) Filed: Nov. 18, 2004

(51) Int. Cl. H01L 21/44

(52) U.S. Cl. 438/597

(57) ABSTRACT

System and method for providing an inter-metal dielectric that prevents or reduces film delamination and contact corrosion defects is provided. A preferred embodiment comprises forming a chemical-mechanical polishing (CMP) stop layer over the surface of an inter-metal dielectric prior to forming interconnects and vias. Interconnect and vias may be formed with a dual-damascene process and filled with a conductive material. After the interconnects and vias are filled with a conductive material, a CMP process planarizes the wafer, leaving at least a portion of the CMP stop layer.

### TECHNICAL FIELD

The present invention relates generally to semiconductors, and more particularly, to an apparatus, and a method of manufacturing, having an inter-metal dielectric that prevents or reduces film delamination and contact corrosion defects.

### BACKGROUND

Generally, semiconductor devices comprise electronic components, such as transistors, capacitors, or the like, formed on a substrate. One or more metal layers are then formed over the electronic components to provide connections between the electronic components and to provide connections to external devices. The metal layers typically comprise an intermetal dielectric layer in which vias and interconnects are formed, usually with a single- or dual-damascene process.

The damascene process typically involves forming a first mask (e.g., a photoresist mask) over the intermetal dielectric layer to define the vias. A first etching process etches the vias partially through the intermetal dielectric layers to the underlying electronic components or other contact point. The first mask is removed, and then a second mask is formed to define interconnects, which are generally larger than and include the area of the vias. A second etching process is then performed to create the interconnects and to complete the vias. Thereafter, the vias and interconnects are filled with a conductive material. A chemical-mechanical polishing (CMP) process or an etchback process may be performed to remove excess conductive material, exposing the intermetal dielectric material.

It is common to utilize fluorosilicate glass (FSG) for the intermetal dielectric layer and copper for the metal layers. When the FSG is exposed to the environment, however, fluorine precipitates may form, which may cause defects. In particular, fluorine precipitates may react with the copper to form copper fluoride defects on the copper surface, or induce copper surface corrosion or copper voids. Furthermore, fluorine precipitates may cause delamination defects when another layer, such as an etch stop layer, is formed on the FSG. The fluorine precipitates may also cause a porous etch stop layer.

Accordingly, there is a need for a system and method for providing an inter-metal dielectric that prevents or reduces film delamination and contact corrosion defects.

### SUMMARY OF THE INVENTION

These and other problems are generally solved or circumvented, and technical advantages are generally achieved, by preferred embodiments of the present invention which provides an apparatus, and a method of manufacture, having an inter-metal dielectric that prevents or reduces film delamination and contact corrosion defects.

In accordance with an embodiment of the present invention, a method for forming interconnects is provided, the method including providing a wafer, forming a dielectric layer on the wafer, forming a stop layer on the dielectric layer, forming an interconnect in the stop layer and the dielectric layer, and planarizing a surface of the wafer such that a portion of the stop layer remains.

In accordance with another embodiment of the present invention, a method for forming interconnects is provided, the method including providing a wafer, forming an first etch stop layer on the wafer, forming a dielectric layer on the etch stop layer, forming a stop layer on the dielectric layer, forming an interconnect in the stop layer and the dielectric layer, and planarizing a surface of the wafer such that a portion of the stop layer remains.

In accordance with still another embodiment of the present invention, a method for forming interconnects is provided, the method including providing a wafer, forming an first etch stop layer over the wafer, forming a first dielectric layer over the first etch stop layer, forming a second etch stop layer over the first dielectric layer, forming a second dielectric layer over the second etch stop layer, forming a stop layer over the second dielectric layer forming an interconnect in the stop layer and the dielectric layer, and planarizing a surface of the wafer such that a portion of the stop layer remains.

In accordance with another embodiment of the present invention, an apparatus having an inter-metal dielectric layer, a stop layer formed on the inter-metal dielectric, and a damascene structure formed in the inter-metal dielectric and the stop layer is provided.

In accordance with still another embodiment of the present invention, an apparatus having a first inter-metal dielectric layer a first etch stop layer formed over the first inter-metal dielectric layer, a second inter-metal dielectric layer, a second etch stop layer formed over the second inter-metal dielectric layer, a stop layer formed on the second inter-metal dielectric layer, and a damascene structure formed in the first inter-metal dielectric layer, the first etch stop layer, the second inter-metal dielectric layer, the second etch stop layer, and the stop layer is provided.

It should be appreciated by those skilled in the art that the conception and specific embodiment disclosed may be readily utilized as a basis for modifying or designing other structures or processes for carrying out the same purposes of the present invention. It should also be realized by those skilled in the art that such equivalent constructions do not depart from the spirit and scope of the invention as set forth in the appended claims.

### BRIEF DESCRIPTION OF THE DRAWINGS

For a more complete understanding of the present invention, and the advantages thereof, reference is now made to the following descriptions taken in conjunction with the accompanying drawings, in which:

FIGS. 1-5 are cross-section views of a wafer during various steps of an embodiment of the present invention; and

FIGS. 6-10 are cross-section views of a wafer during various steps of an embodiment of the present invention.

### DETAILED DESCRIPTION OF ILLUSTRATIVE EMBODIMENTS

The making and using of the presently preferred embodiments are discussed in detail below. It should be appreciated, however, that the present invention provides many applicable inventive concepts that can be embodied in a wide variety of specific contexts. The specific embodiments discussed are merely illustrative of specific ways to make and use the invention, and do not limit the scope of the invention.

The present invention will be described with respect to embodiments in a specific context, namely forming copper interconnects in an intermetal dielectric layer. The invention may also be applied, however, to other designs in which it is desirable to limit contamination between materials or to increase adhesive qualities of successive layers.

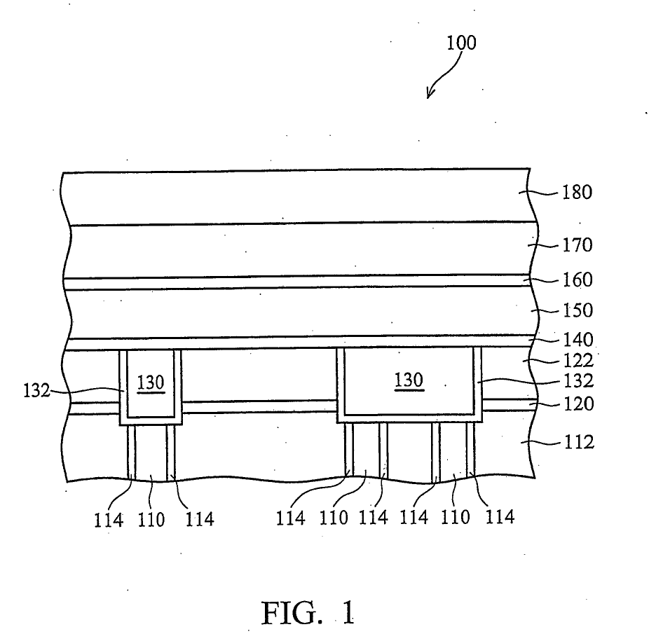

FIGS. 1-5 illustrate cross-section views of a semiconductor device 100 during various steps of a first embodiment of the present invention in which a damascene process is used to fabricate metal interconnects. Starting with FIG. 1, a semiconductor device 100 comprising contacts 110 formed in an inter-layer dielectric (ILD) 112 is shown. It should be noted that the contacts 110 may connect to any type of semiconductor structure (not shown), such as transistors, capacitors, resistors, or the like, or an intermediate contact point, such as a metal interconnect or the like.

The ILD 112 may be formed, for example, of a low-K dielectric material, silicon oxide, phosphosilicate glass (PSG), borophosphosilicate glass (BPSG), fluorinated silicate glass (FSG), or the like, by any suitable method known in the art. In an embodiment, the ILD 112 comprises an oxide that may be formed by chemical vapor deposition (CVD) techniques using tetra-ethyl-ortho-silicate (TEOS) and oxygen as a precursor. The ILD 112 is preferably about 2000 Å to about 6000 in thickness. Other thicknesses and materials may be used.

Contacts 110 may be formed in the ILD 112 in accordance with known photolithography and etching techniques. Generally, photolithography techniques involve depositing a photoresist material, which is masked, exposed, and developed to expose portions of the ILD layer 112 that are to be removed. The remaining photoresist material protects the underlying material from subsequent processing steps, such as etching. In the preferred embodiment, photoresist material is utilized to create a patterned mask to define contacts 110. The etching process may be an anisotropic or isotropic etch process, but preferably is an anisotropic dry etch process. After the etching process, any remaining photoresist material may be removed.

The contacts 110 may comprise a barrier/adhesion layer 114 to prevent diffusion and provide better adhesion between the contacts 110 and the ILD 112. In an embodiment, the barrier layer 114 is formed of one or more layers of titanium, titanium nitride, tantalum, tantalum nitride, or the like deposited by CVD techniques to a combined thickness of about 50 Å to about 500 Å. The contacts 110 may be formed of a highly-conductive, low-resistive metal, elemental metal, transition metal, or the like. In an exemplary embodiment in which contacts 110 are formed of tungsten, the contacts 110 may be deposited by CVD techniques known in the art.

A first etch stop layer 120 may be formed on the surface of the ILD 112, and a first inter-metal dielectric (IMD) 122 may be formed on the first etch stop layer 120. It should be noted that a planarization step, which may be performed by a chemical-mechanical polishing (CMP) process, may be performed prior to the formation of the first etch stop layer 120. The first etch stop layer 120 may be formed of any material that provides a high etch selectivity between the first etch stop layer 120 and the subsequently-formed first IMD layer 122.

The first IMD layer 122 is preferably formed of a low-K dielectric material, such as fluorosilicate glass (FSG) or the like. In an exemplary embodiment, the first IMD layer 122 is formed of FSG, and the first etch stop layer 120 is formed of SiN, SiC, a low-k dielectric film, or the like. An SiN layer may be formed, for example, by plasma-enhanced chemical-vapor deposition (PECVD) techniques, and the FSG layer may be formed by PECVD techniques or high density plasma chemical-vapor deposition (HDP). Preferably, the first etch stop layer 120 is about 150 Å to about 600 Å in thickness, and the first IMD layer 122 is about 2000 to about 4000 Å in thickness.

First interconnects 130 are formed in the first IMD layer 122. The first interconnects 130 may be formed by using standard photolithography techniques known in the art. Generally, a photoresist material is patterned and an etching process, such as an anisotropic or isotropic etch process, is performed to remove a portion of the first IMD layer 122 corresponding to the first interconnects 130. After the etching process, the first interconnects 130 may be filled with a conductive material such as one or more layers of metals, elemental metals, transition metals, or the like. In an exemplary embodiment, the conductive material used to fill the first interconnects 130 is copper deposited by electroplating (ECP). Other conductive materials and processes, however, may be used.

It should be noted that the first interconnects 130 may comprise a barrier/adhesion layer 132 formed of one or more layers of conductive materials, such as titanium, titanium nitride, tantalum, tantalum nitride or the like. In an exemplary embodiment wherein the first interconnects 130 are formed of copper, the adhesion/barrier layer 132 may comprise a thin layer of tantalum nitride followed by a thin layer of tantalum. The tantalum nitride and tantalum layers may be formed, for example, by CVD, physical vapor deposition (PVD), or the like and may have a combined thickness of about 100 Å to about 500 Å. It should be noted that a planarization step, which may be performed by one or more CMP processes, may be performed to remove the excess barrier layer material and/or conductive material.

A second etch stop layer 140 may be formed on the surface of the first IMD layer 122 and first interconnects 130, and a second IMD layer 150 may be formed over the second etch stop layer 140. The second etch stop layer 140 may be formed of any material that provides a high etch selectivity between the second etch stop layer 140 and the subsequently formed second IMD layer 150. In an exemplary embodiment, the second etch stop layer 140 is formed of SiN, SiC, a low-k dielectric film, or the like deposited by CVD techniques, and the second IMD layer 150 may be formed of FSG by a process similar to the process used to form the first IMD layer 122. Other materials and processes may be used. The second etch stop layer 140 is preferably about 250 Å to about 750 Å in thickness, and the second IMD layer 150 is preferably about 2000 Å to about 5000 Å in thickness.

A third etch stop layer 160 is formed over the second IMD layer 150, and a third IMD layer 170 is formed over the third etch stop layer 160. As will be discussed in greater detail below, the third etch stop layer 160 will be utilized in an etching step to form vias and interconnects. It should be noted that the second etch stop layer 140 and the third etch stop layer 160 may be formed of different or the same material, and the second IMD layer 150 and the third IMD layer 170 may be formed of different materials or the same material.

In an exemplary embodiment, the third IMD layer 170 is formed of FSG by a process similar to the process used to form the first IMD layer 122 and the third etch stop layer 160 is formed of SiN, SiC, a low-k dielectric film, or the like. The third etch stop layer 160 is preferably about 250 Å to about 750 Å in thickness, and the third IMD layer 170 is preferably about 2000 Å to about 5000 Å in thickness. Other materials, processes, and thicknesses may be used.

A stop layer 180 is formed over the third IMD layer 170. The stop layer 180 prevents or reduces contamination or other defects caused by exposing the third IMD layer 170, which is preferably formed of FSG. The contamination may include, for example, contamination of the material used to fill interconnects and vias in later steps, surface delamination of layers deposited on the third IMD layer 170, and the like.

The stop layer 180 may comprise one or more layers of organic or inorganic materials and may comprise a non-conductive metal compound, such as TaNₓO_{y} or the like, or a non-metal, such as silicon oxynitride, silicon nitride, carbon-containing silicon nitride, silicon oxide, carbon-containing silicon oxide, SiON, SiC, SiCN, SiCO, SiN, SiO, SiOCH, or the like, and may be formed by physical vapor deposition, chemical vapor deposition, atomic layer deposition, ion beam, or the like techniques. In an embodiment in which the third IMD layer 170 comprises FSG, the stop layer 180 may be silicon oxynitride (SiON) formed by PECVD techniques. Embodiments of the present invention may use a stop layer 180 having a thickness less than about 1200 Å, less than about 600 Å, less than about 300 Å, or less than about 100 Å. Other materials, processes, and thicknesses may be used.

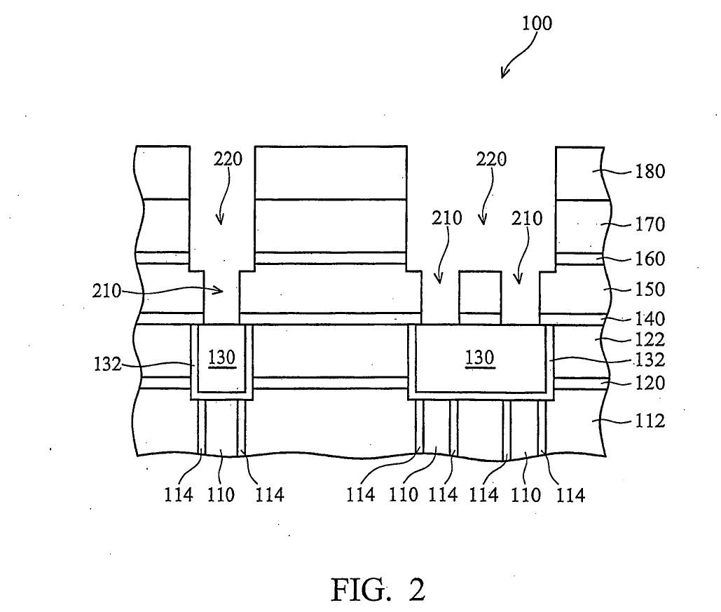

FIG. 2 illustrates the semiconductor device 100 of FIG. 1 after a dual-damascene etching process has been performed to form vias 210 and interconnects 220 in accordance with an embodiment of the present invention. In an embodiment of the present invention, vias 210 and interconnects 220 are formed by a two-step etching process. First, a first mask (not shown) is applied to define the pattern of the vias, and an etching process is performed to etch the vias 210 to the third etch stop layer 160. The mask may be, for example, a photoresist material that has been applied, patterned, exposed, and developed. Other types of masks may be used.

Second, a second mask (not shown) may be applied in the same manner as the first mask to define the pattern of the interconnects 220. A second etching process then etches the vias 210 in the second IMD layer 150 and the interconnects 220 in the third IMD layer 170. Thereafter, any remaining photoresist material may be removed.

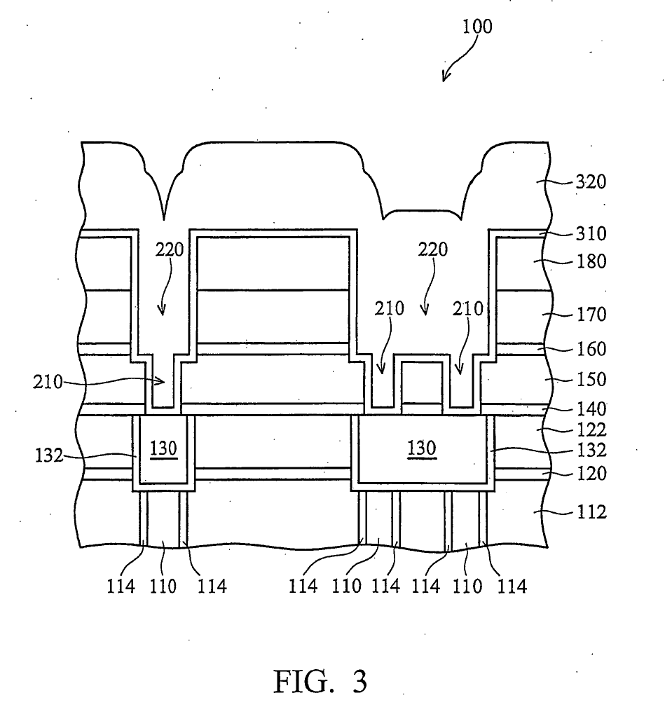

FIG. 3 illustrates the semiconductor device 100 of FIG. 2 after a barrier/adhesion layer 310 and the vias 210 and interconnects 220 have been filled with a conductive material 320. The barrier/adhesion layer 310 may be formed of one or more layers of conductive materials, such as titanium, titanium nitride, tantalum, tantalum nitride, or the like. In an exemplary embodiment, the barrier/adhesion layer 310 is formed of a thin layer of tantalum nitride and a thin layer of tantalum deposited by PVD techniques. In this embodiment, the combined thickness of the tantalum nitride and tantalum layers is about 50 Å to about 500 Å.

The conductive material 320 used to fill the vias 210 and the interconnects 220 may be, for example, copper. The vias 210 and the interconnects 220 may be filled, for example, by performing a blanket deposition process to a thickness such that the vias 210 and interconnects 220 are at least substantially filled. The conductive materials 320 may comprise metals, elemental metals, transition metals, or the like. In an exemplary embodiment, the conductive material 320 is copper. As illustrated in FIG. 3, this process also covers the surface of the stop layer 180.

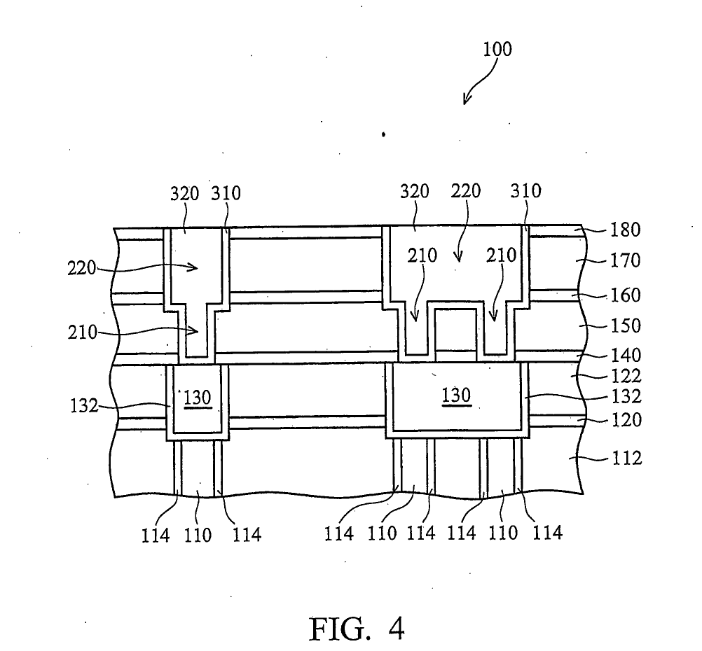

FIG. 4 illustrates the semiconductor device 100 of FIG. 3 after a planarization process has been performed in accordance with an embodiment of the present invention. The planarization process removes the excess material used to form the barrier/adhesion layer 310, the vias 210, and the interconnects 220. The planarization process may be performed by a CMP process.

In accordance with the present teachings, the planarization process does not entirely remove the stop layer 180. In this manner, the stop layer 180 prevents fluoride precipitates from causing film delamination and/or porous etch stop layers. Furthermore, the stop layer 180 prevents the fluoride from reacting with the copper interconnects and vias to form copper fluoride defects, surface corrosion, or copper voids along the surface of the interconnects 220.

An optional surface treatment may be performed to the conductive material 320 and the stop layer 180 after the planarization process. The optional surface treatment may be in situ or ex situ, as examples. For example, the semiconductor device 100 may be treated in situ by leaving the semiconductor device 100 in the processing tool and treating the semiconductor device 100. Alternatively, the semiconductor device 100 may be pretreated ex situ by moving the semiconductor device 100 to a separate processing chamber or tool for the treatment process. The surface treatment may be performed, for example, by thermal treatment, plasma treatment, chemical treatment, or de-ionized water rinse. It has been found that the optional surface treatment may prevent or reduce the reaction between the copper and the environment to form Cu₂O, which has poor adhesion qualities with the cap layer formed in a subsequent process. This prevents or reduces film delamination.

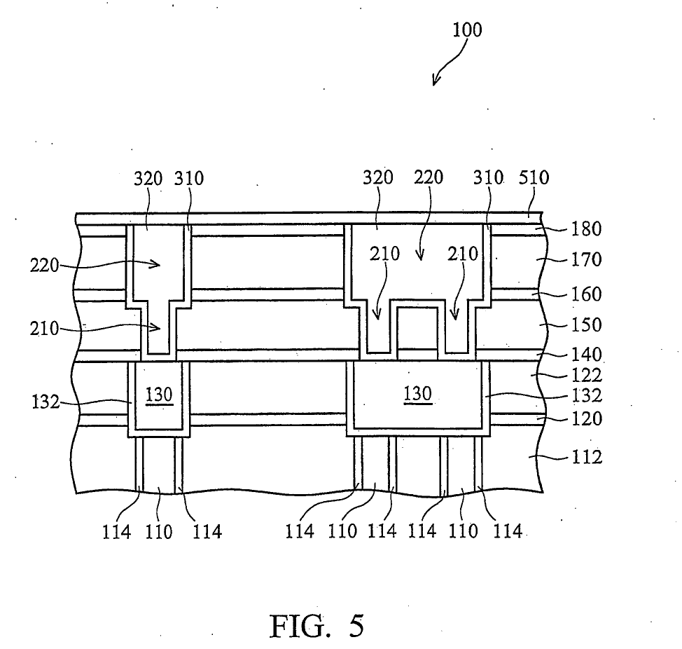

FIG. 5 illustrates the semiconductor device 100 of FIG. 4 after a cap layer 510 has been formed. In an embodiment, the cap layer 510 may be formed of silicon nitride and may act as an etch stop for subsequent processing steps or provide further protection from the environment. The cap layer 510 may also be formed of other dielectric films, such as tantalum oxynitride, carbon-containing silicon nitride, silicon oxide, carbon-containing silicon oxide, TaNₓO_{y}, SiC, SiCN, SiCO, SiO, SiOCH, or the like. Thereafter, standard processing techniques, such as depositing and patterning metal layers, forming vias, dicing, packaging, and the like, may be utilized to complete fabrication of the semiconductor device.

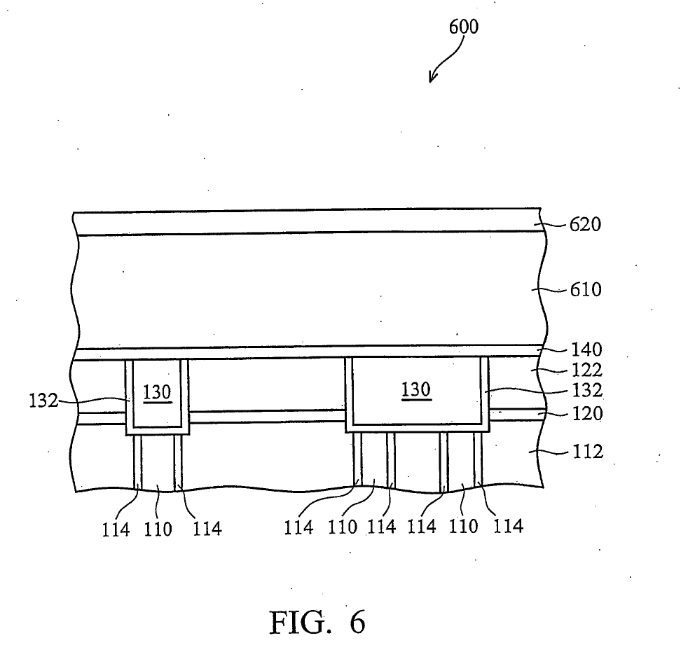

FIGS. 6-10 illustrate cross-section views of a semiconductor device 600 during various steps of a second embodiment of the present invention in which a damascene process is used to fabricate metal interconnects. As will be discussed in greater detail below, this second embodiment is similar to the first embodiment except that a single intermetal dielectric layer is utilized. This is illustrated starting in FIG. 6, wherein like reference numerals refer to like elements discussed above with reference to FIG. 1.

Accordingly, FIG. 6 illustrates a semiconductor device 600 having a second IMD layer 610 formed over the second etch stop layer 140. The second etch stop layer 140 may be formed of any material having a high etch selectivity as compared to the second IMD layer 610, such as SiN, SiC, a low-k dielectric, or the like. In an exemplary embodiment, the second IMD layer 610 is formed of FSG by a process similar to the process used to form the first IMD layer 122. In this exemplary embodiment, the second etch stop layer 140 is formed of SiN. Other materials and processes may be used. The second IMD layer 610 is preferably about 3000 Å to about 20000 Å in thickness.

A stop layer 620 is formed over the second IMD layer 610. The stop layer 620 prevents or reduces contamination or other defects caused by exposing the second IMD layer 610, which is preferably formed of FSG. The contamination may include, for example, contamination of the material used to fill interconnects and vias in later steps, surface delamination of layers deposited on the second IMD layer 610, and the like.

The stop layer 620 may comprise one or more layers of organic or inorganic materials and may comprise non-conductive metal compounds, such as TaNₓO_{y} or the like, or non-metals, such as silicon oxynitride, silicon nitride, carbon-containing silicon nitride, silicon oxide, carbon-containing silicon oxide, SiON, SiC, SiCN, SiCO, SiN, SiO, SiOCH, or the like, and may be formed by physical vapor deposition, chemical vapor deposition, atomic layer deposition, ion beam, or the like techniques. In an embodiment in which the second IMD layer 610 comprises FSG, the stop layer 620 may be silicon oxynitride (SiON) formed by PECVD techniques. Embodiments of the present invention may use an stop layer 620 having a thickness less than about 1200 Å, less than about 600 Å, less than about 300 Å, or less than about 100 Å. Other materials, processes, and thicknesses may be used.

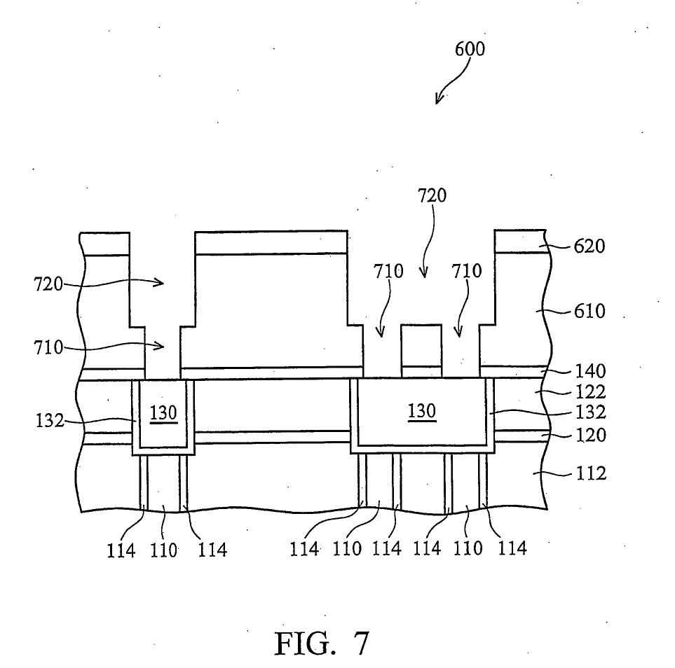

FIG. 7 illustrates the semiconductor device 600 of FIG. 6 after a dual-damascene etching process has been performed to form vias 710 and interconnects 720 in accordance with an embodiment of the present invention. First, a first mask (not shown) is applied to define the pattern of the vias 710, and an etching process may be performed for a predetermined amount of time or using an endpoint detection. The mask may be, for example, a photoresist material that has been applied, patterned, exposed, and developed. After the etching process, the remaining photoresist material may be removed. Other types of masks, or additional masks, may be used.

Next, a second mask (not shown) may be applied in a manner similar to the first mask to define the pattern of the interconnects 720. A second etching process then etches the interconnects 720 and completes the etching of the vias 710. Thereafter, any remaining photoresist material may be removed.

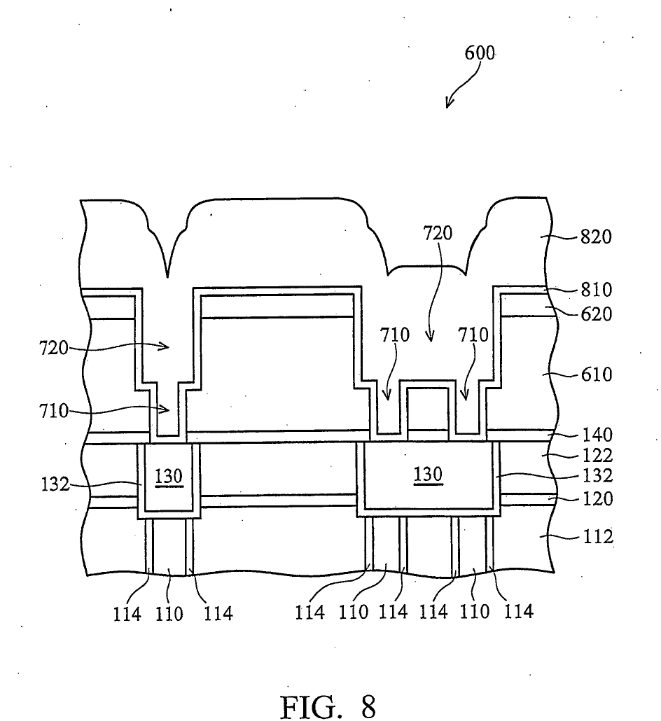

FIG. 8 illustrates the semiconductor device 600 of FIG. 7 after a barrier/adhesion layer 810 and the vias 710 and interconnects 720 have been filled with a conductive material. The barrier/adhesion layer 810 may be formed of one or more layers of a conductive material, such as titanium, titanium nitride, tantalum, tantalum nitride, or the like. In an embodiment, the barrier/adhesion layer 810 is formed of a thin layer of tantalum nitride and a thin layer of tantalum deposited by PVD techniques. In this embodiment, the combined thickness of the tantalum nitride and tantalum layers is about 100 Å to about 500 Å.

The conductive material 820 used to fill the vias 710 and the interconnects 720 may be, for example, copper. The vias 710 and the interconnects 720 may be filled, for example, by performing a blanket deposition process to a thickness such that the vias 710 and interconnects 720 are substantially filled. The conductive materials 820 may comprise metals, elemental metals, transition metals, or the like. In an exemplary embodiment, the conductive material 820 is copper. As illustrated in FIG. 8, this process also covers the surface of the stop layer 620.

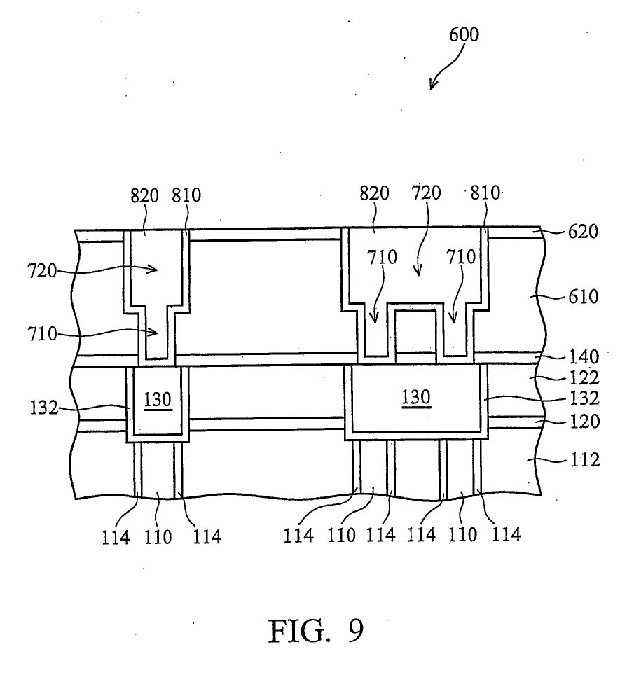

FIG. 9 illustrates the semiconductor device 600 of FIG. 8 after a planarization process has been performed in accordance with an embodiment of the present invention. The planarization process removes the excess conductive material used to form the barrier/adhesion layer 810, the vias 710 and the interconnects 720. The planarization process may be performed by a CMP process.

As illustrated in FIG. 9, the planarization process does not entirely remove the stop layer 620. In this manner, the stop layer 620 prevents fluoride precipitates from causing film delamination and/or porous etch stop layers. Furthermore, the stop layer 620 prevents the fluoride from reacting with the copper interconnects and vias and forming copper fluoride defects, surface corrosion, or copper voids along the surface of the interconnects 720.

An optional surface treatment may be performed to the conductive material 820 and the stop layer 620 after the planarization process. The optional surface treatment may be in situ ex situ, as examples. For example, the semiconductor device 600 may be treated in situ by leaving the semiconductor device 600 in the processing tool and treating the semiconductor device 600. Alternatively, the semiconductor device 600 may be pretreated ex situ by moving the semiconductor device 600 to a separate processing chamber or tool for the treatment process. The surface treatment may be formed, for example, by thermal treatment, plasma treatment, chemical treatment, or de-ionized water rinse. As discussed above, the optional surface treatment may help prevent or reduce film delamination between the copper and a subsequently formed cap layer.

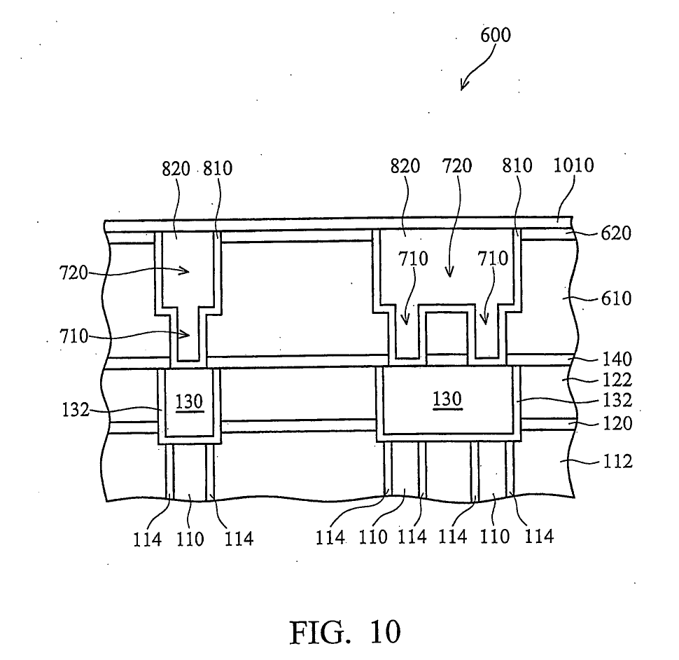

FIG. 10 illustrates the semiconductor device 600 of FIG. 9 after a cap layer 1010 has been formed. In an embodiment, the cap layer 1010 may be formed of SiN and may act as an etch stop for subsequent processing steps or provide further protection from the environment. The cap layer 1010 may also be formed of other dielectric film, such as tantalum oxynitride, carbon-containing silicon nitride, silicon oxide, carbon-containing silicon oxide, TaNₓO_{y}, SiC, SiCN, SiCO, SiO, SiOCH, or the like. Thereafter, standard processing techniques, such as depositing and patterning metal layers, forming vias, dicing, packaging, and the like, may be utilized to complete fabrication of the semiconductor device.

Although the present invention and its advantages have been described in detail, it should be understood that various changes, substitutions and alterations can be made herein without departing from the spirit and scope of the invention as defined by the appended claims. For example, different types of materials and processes may be varied while remaining within the scope of the present invention.

Moreover, the scope of the present application is not intended to be limited to the particular embodiments of the process, machine, manufacture, composition of matter, means, methods and steps described in the specification. As one of ordinary skill in the art will readily appreciate from the disclosure of the present invention, processes, machines, manufacture, compositions of matter, means, methods, or steps, presently existing or later to be developed, that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps.

1. A method for forming interconnects, the method comprising:
providing a substrate;
forming a first etch stop layer on the substrate;
forming a fluorine-containing dielectric layer on the first etch stop layer;
forming a stop layer on the fluorine-containing dielectric layer;
forming an interconnect in the stop layer and the fluorine-containing dielectric layer;
planarizing a surface of the substrate such that a portion of the stop layer remains; and
forming a cap layer on the stop layer and the interconnect.

2. The method of claim 1, wherein the forming of the interconnect includes forming a via in the fluorine-containing dielectric layer by a dual-damascene process.

3. The method of claim 1, wherein the planarizing is performed by a chemical-mechanical polishing (CMP) process, and wherein the stop layer acts as a CMP stop layer for the CMP process.

4. The method of claim 1, further comprising performing a surface treatment after the planarizing.

5. The method of claim 4, wherein the surface treatment comprises an in-situ treatment.

6. The method of claim 4, wherein the surface treatment comprises an ex-situ treatment.

7. The method of claim 4, wherein the surface treatment comprises a thermal treatment.

8. The method of claim 4, wherein the surface treatment comprises a plasma treatment.

9. The method of claim 4, wherein the surface treatment comprises a chemical treatment.

10. The method of claim 4, wherein the surface treatment comprises a de-ionized water rinse.

11. The method of claim 1, wherein the fluorine-containing dielectric layer comprises a low-K dielectric film.

12. The method of claim 1, wherein the fluorine-containing dielectric layer comprises fluorinated silicate glass (FSG).

13. The method of claim 1, wherein the first etch stop layer comprises SiN, SiC, or a low-K dielectric film.

14. The method of claim 1, wherein the forming the stop layer is performed by physical vapor deposition, chemical vapor deposition, atomic layer deposition, or ion-beam techniques.

15. A method for forming interconnects, the method comprising:
providing a substrate;
forming a first etch stop layer over the substrate;
forming a first dielectric layer over the first etch stop layer;
forming a second etch stop layer over the first dielectric layer;
forming a second dielectric layer over the second etch stop layer;
forming a stop layer over the second dielectric layer;
forming an interconnect in the stop layer and the second dielectric layer;
planarizing a surface of the substrate such that a portion of the stop layer remains, and
forming a cap layer on the stop layer and the interconnect, wherein at least one of the first dielectric layer and the second dielectric layer comprises a fluorine-containing dielectric layer.

16. The method of claim 15, wherein the forming the interconnect includes forming a via in the first dielectric layer by a dual-damascene process, and wherein the second etch stop layer acts as an etch stop for a first etching process in the dual-damascene process.

17. The method of claim 15, wherein the planarizing is performed by a chemical-mechanical polishing (CMP) process, and wherein the stop layer acts as a CMP stop layer for the CMP process.

18. The method of claim 15, further comprising performing a surface treatment after the planarizing.

19. The method of claim 18, wherein the surface treatment comprises an in-situ treatment.

20. The method of claim 18, wherein the surface treatment comprises an ex-situ treatment.

21. The method of claim 18, wherein the surface treatment comprises a thermal treatment.

22. The method of claim 18, wherein the surface treatment comprises a plasma treatment.

23. The method of claim 18, wherein the surface treatment comprises a chemical treatment.

24. The method of claim 18, wherein the surface treatment comprises a de-ionized water rinse.

25. The method of claim 15, wherein the first and second dielectric layers comprise a low-K dielectric film.

26. The method of claim 15, wherein the first and second dielectric layers comprise fluorinated silicate glass (FSG).

27. The method of claim 15, wherein, the first and second etch stop layers comprise SiN, SiC, or a low-K dielectric film.

28. The method of claim 15, wherein the stop layer comprises one or more layers of SiON, SiC, SiCN, SiCO, SiN, SiO, SiOCH, or a combination thereof.

29. The method of claim 15, wherein the forming the stop layer is performed by physical vapor deposition, chemical vapor deposition, atomic layer deposition, or ion-beam techniques.

30.-44. (canceled)
